(19) United States
(12) Patent Application Publication
(10) Pub. No.: US 2006/0208317 A1
(43) Pub. Date: Sep. 21, 2006

(54) LAYOUT STRUCTURE OF SEMICONDUCTOR CELLS

(76) Inventor: Tsuoe-Hsiang Liao, Hsinchu City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/907,030

(22) Filed: Mar. 17, 2005

(51) Int. Cl. H01L 29/94

(52) U.S. Cl. 257/369

(57) ABSTRACT

A layout structure of semiconductor cells is described. The layout structure includes multiple semiconductor cells, wherein at least one pair of cells has an overlap member part between them, so that the area of the pair of cells is smaller than the sum of respective areas of the two cells.

### BACKGROUND OF THE INVENTION

1. Field of the Invention

The present invention relates to a structure of semiconductor apparatus. More particularly, the present invention relates to a layout structure of semiconductor cells in an integrated circuit (IC).

2. Description of the Related Art

Recently, semiconductor IC designs are mostly based on “cells” to simplify the design process, while current VLSI circuits are essentially constituted of numerous standard cells. A standard cell is a block of logic having a specific function like NAND gate or NOR gate or a block of any other type of circuit, which has a fixed height and is carefully designed in circuit layout to optimize the use of die space. The fundamental knowledge of standard cell can be found in, for example, the disclosure of U.S. Pat. No. 5,798,541. There are usually thousands of different standard cell types in a particular software library for a particular semiconductor manufacturing process.

FIG. 1 illustrates two adjacent standard cells 100 and 200 in an integrated circuit that are arranged in the cell width (W) direction perpendicular to the cell height (H) direction, wherein each standard cell includes a CMOS device. Specifically, the cell 100 includes an NMOS transistor (abbreviated to “NMOS” hereinafter) 110 and a PMOS transistor (abbreviated to “PMOS” hereinafter) 120, and the cell 200 includes an NMOS 210 and a PMOS 220. The cells 100 and 200 have the same height “H”, and the combined width (WT0) of the cells 100 and 200 is equal to the sum of respective widths (W1 & W2) of the cells 100 and 200. Therefore, the combined area of the cells 100 and 200 is equal to the sum of respective areas of the cells 100 and 200. Accordingly, the combined area of all standard cells in an integrated circuit is equal to the sum of respective areas of the same.

However, since the integration degree of IC devices is required higher and higher, the die space is often insufficient as standard cells are used in IC designs.

### SUMMARY OF THE INVENTION

In view of the foregoing, this invention provides a layout structure of semiconductor cells to increase the device density of an integrated circuit.

The layout structure of semiconductor cells of this invention includes multiple semiconductor cells, wherein at least one pair of cells includes at least one overlap member part between them, so that the area of the pair of cells is smaller than the sum of respective areas of the two cells.

According to a preferred embodiment of this invention, the above semiconductor cells may include multiple standard cells that have the same height and are arranged into multiple rows in a width direction perpendicular to the cell height direction. The overlap member part may be formed by overlapping, along the cell width direction, the corresponding member parts in the two standard cells. The aforementioned multi-row arrangement of standard cells can be readily understood by referring to, for example, U.S. Pat. No. 5,798,541.

Moreover, the pair of standard cells includes a first and a second cells, wherein the first cell may include a first CMOS device and the second cell may include a second CMOS device, for example. The overlap member parts include, for example, the N-well (or N-substrate layer) of PMOS and the P-well (or P-substrate layer) of NMOS, while the combination of N-well and P-well, N-substrate layer and P-well, or N-well and P-substrate layer is possible. The N-well/substrate layer with overlap is formed by overlapping the N-well/substrate layer of the PMOS of the first CMOS device and that of the PMOS of the second CMOS device. The P-well/substrate layer with overlap is formed by overlapping the P-well/substrate layer of the NMOS of the first CMOS device and that of the NMOS of the second CMOS device.

The pair of cells can be further overlapped with each other to form more overlap member parts between them. For example, the N-type source/drain (S/D) region of the NMOS of the first CMOS (abbreviated to “the first N-type S/D region” later) may overlap with the N-type S/D region of the NMOS of the second CMOS (abbreviated to “the second N-type S/D region” later). The P-type S/D region of the PMOS of the first CMOS (abbreviated to “the first P-type S/D region” later) may overlap with the P-type S/D region of the PMOS of the second CMOS (abbreviated to “the second P-type S/D region” later). In such cases, when each of the first and second, N-type and P-type S/D regions has a diffusion region of the same conductivity type at its periphery, the diffusion region of the first N-type S/D region overlaps with that of the second N-type S/D region, and the diffusion region of the first P-type S/D region overlaps with that of the second P-type S/D region.

Moreover, the contact(s) on the first N-type S/D region may overlap with the contact(s) on the second N-type S/D region, and the contact(s) on the first P-type S/D region may overlap with the contact(s) on the second P-type S/D region.

Since there are overlap member parts between the cells in the layout structure of semiconductor cells of this invention, the combined area of the cells is smaller than the sum of respective areas of the same. Therefore, the device density of the integrated circuit can be increased.

It is to be understood that both the foregoing general description and the following detailed description are exemplary, and are intended to provide further explanation of the invention as claimed.

### BRIEF DESCRIPTION OF THE DRAWINGS

FIG. 1 illustrates two adjacent CMOS-including standard cells in the prior art.

FIG. 2 illustrates a layout structure formed by overlapping wells/substrate layers of the two standard cells shown in FIG. 1 according to a preferred embodiment of this invention.

FIG. 3 illustrates a layout structure formed by further overlapping S/D regions of the two standard cells shown in FIG. 2 according to the preferred embodiment of this invention.

FIG. 4 illustrates two adjacent CMOS-including standard cells in the prior art, wherein each standard cell further includes diffusion regions, contacts and conductive layers connected with the contacts.

FIG. 5 illustrates a layout structure formed by overlapping wells, S/D regions, diffusion regions and contacts, respectively, of the two standard cells shown in FIG. 4 according to the preferred embodiment of this invention.

### DESCRIPTION OF THE PREFERRED EMBODIMENTS

The present invention will be further explained with two adjacent CMOS-including standard cells as an example. Though only two cells are illustrated in the drawings, it does not mean that this invention is applied to an IC including only two cells. Because an IC based on standard cells absolutely includes much more than 2 cells, one of ordinary skills surely knows that the two standard cells being illustrated are merely two selected from numerous standard cells in an IC to be an example.

In addition, this invention is not restricted to apply to CMOS-including standard cells, and can be applied to cells including any other types of devices if only there is at least one pair of overlappable member parts between two adjacent cells. Moreover, this invention is either not restricted to the cases where two adjacent cells in the same row merely overlap with each other, and can be readily applied to the cases where any two adjacent cells in 3 or more contiguous cells of the same row are overlapped with each other.

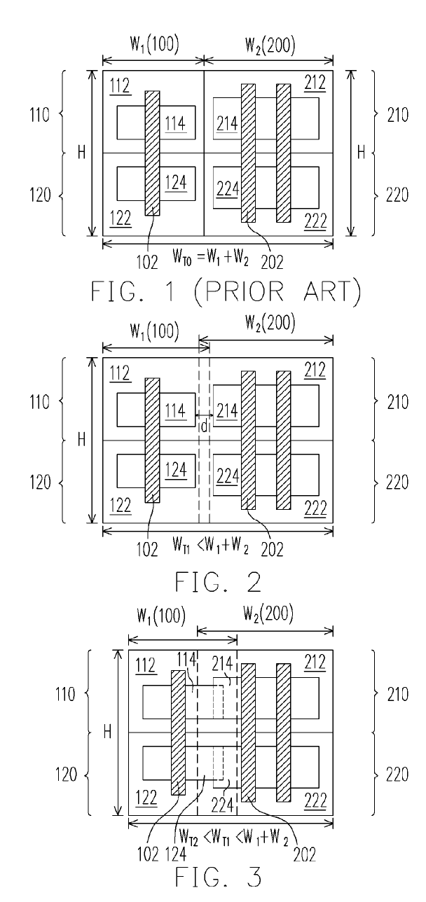

FIG. 2 illustrates a layout structure formed by overlapping wells/substrate layers of the two standard cells shown in FIG. 1 according to the preferred embodiment of this invention. Specifically, the P-well/substrate layer 112 of the NMOS 110 of the cell 100 overlaps with the P-well/substrate layer 212 of the NMOS 210 of the cell 200, and the N-well/substrate layer 122 of the PMOS 120 of the cell 100 overlaps with the N-well/substrate layer 222 of the NMOS 220 of the cell 200. As well known in the art, the well design of CMOS may be a combination of N-well and P-well, N-well and P-substrate layer, or N-substrate layer and P-well. Accordingly, in this embodiment, it is possible that the P-wells 112 and 212 overlap with each other and the N-wells 122 and 222 overlap with each other, that the P-substrate layers 112 and 212 overlap with each other and the N-wells 122 and 222 overlap with each other, or that the P-wells 112 and 212 overlap with each other and the N-substrate layers 122 and 222 overlap with each other. In addition, the CMOS of the cell 100 further includes a gate line 102, and the CMOS of the cell 200 further includes a gate line 202.

Moreover, if the N-type S/D region 114 of the NMOS 110 of the cell 100 and the N-type S/D region 214 of the NMOS 210 of the cell 200 must be biased at different time, or if the voltages respectively applied to 114 and 214 are different, there is preferably a certain distance (d) between 114 and 214 to avoid mutual interference between the cells 100 and 200. Analogously, there may be a certain distance between the P-type S/D region 124 of the PMOS 120 of the cell 100 and the P-type S/D region 224 of the PMOS 220 of the cell 200 to avoid mutual interference.

It is noted that in the embodiment illustrated in FIG. 2, the combined width (WT1) of the cells 100 and 200 is smaller than the sum of respective widths (W1 & W2) of the same. That is, the combined area of the cells 100 and 200 is smaller than the sum of respective areas of the same.

Referring to FIG. 3, except the overlap between wells/substrate layers, the overlap area between the standard cells 100 and 200 can be further increased to make overlap between the N-type S/D regions 114 and 214 as well as overlap between the P-type S/D regions 124 and 224, especially when the N-type S/D region 114 of the NMOS 110 and the that (214) of the NMOS 210 can be applied with the same voltage at the same time and so can the P-type S/D regions 124 and 224. In such a case, the combined width (WT2) of the cells 100 and 200 is even smaller than the width “WT1” in the case of FIG. 2, which means that more die space can be saved.

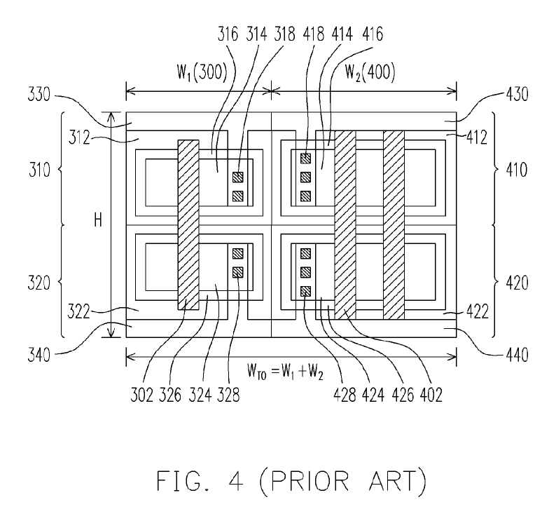

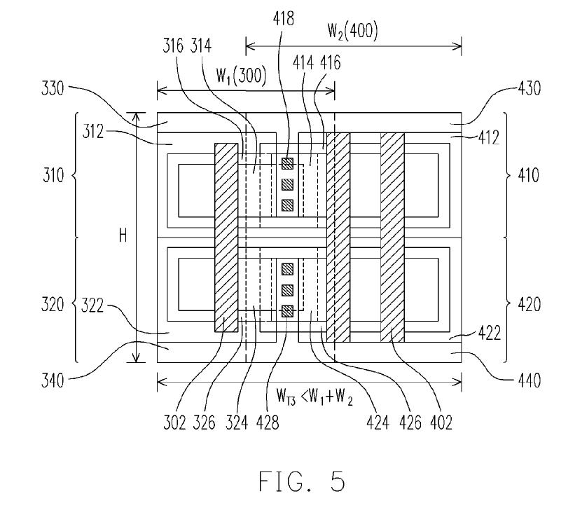

Except the above gate lines, wells and S/D regions, the above two CMOS-including standard cells may further include diffusion regions, contacts and conductive line layers connected with the contacts. The conventional layout of such two cells is illustrated in FIG. 4, for example. As shown in FIG. 4, the N-type diffusion region 316 is at the periphery of the N-type S/D region 314, the N-type diffusion region 416 is at the periphery of the N-type S/D region 414, the P-type diffusion region 326 is at the periphery of the P-type S/D region 324, and the P-type diffusion region 426 is at the periphery of the P-type S/D region 424. The contacts 318, 328, 418 and 428 are disposed on the S/D regions 314, 324, 414 and 424, respectively, and the conductive line layers 330, 340, 430 and 440 are connected with the contacts 31 8, 328, 41 8 and 428, respectively. The conductive line layers 330 and 430 may be a VCC line, and the conductive line layers 340 and 440 may be a VSS line. The cell 300 or 400 should further include some local interconnect to have a specific function, such as, the function of NOR gate or NAND gate.

Referring to FIG. 5, when the S/D regions in cells 300 and 400 are overlapped, the N-type diffusion 316 overlap with the N-type diffusion 416, and the P-type diffusion 326 overlap with the P-type diffusion 426. In addition, if the conductive line layers 330 and 430 are applied with the same voltage at the same time in use, the conductive line layers 330 and 430 can be overlapped with each other. Similarly, if the conductive line layers 340 and 440 are applied with the same voltage at the same time in use, the conductive line layers 340 and 440 can be overlapped with each other.

Moreover, when the N-type S/D regions 314 and 414 respectively in cells 300 and 400 are overlapped, it is feasible to further make the contacts 318 of the former overlap with the contacts 41 8 of the latter. Similarly, when the P-type S/D regions 324 and 424 are overlapped, it is feasible to further make the contacts 328 of the former overlap with the contacts 428 of the latter. In such cases, the combined width (WT3) of the cells 300 and 400 is also smaller than the sum of respective widths (W1 & W2) of the same, as in the above embodiments.

In summary, for the two adjacent CMOS-including standard cells in the above preferred embodiment of this invention, it is possible to at least make overlap between the wells/substrate layers, or further make overlap between the S/D regions, or even further make overlap between diffusion regions, between conductive line layers and/or between contacts. In any of the cases, however, the combined area of the two cells can be smaller than the sum of respective areas of the same. Accordingly, the combined area of all cells is smaller than the sum of respective areas of the same, so that the device density of the integrated circuit can be increased.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A layout structure of semiconductor cells, comprising:
a plurality of semiconductor cells, wherein at least two adjacent cells include at least one overlap member part between them, so that the area of the two cells is smaller than a sum of respective areas of the two cells.

2. The layout structure of claim 1, wherein the semiconductor cells include a plurality of standard cells that have the same height and are arranged into a plurality of rows in a width direction of the cells perpendicular to a height direction of the cells.

3. The layout structure of claim 2, wherein the overlap member part is formed by overlapping, along the width direction of the cells, corresponding member parts in the two cells.

4. The layout structure of claim 3, wherein the two cells comprise a first cell and a second cell, wherein the first cell comprises a first CMOS device and the second cell comprises a second CMOS device.

5. The layout structure of claim 4, wherein
the first CMOS device comprises a first N-substrate layer and a first P-well;
the second CMOS device comprises a second N-substrate layer and a second P-well;
the first N-substrate layer overlaps with the second N-substrate layer; and
the first P-well overlaps with the second P-well.

6. The layout structure of claim 4, wherein
the first CMOS device comprises a first N-well and a first P-substrate layer;
the second CMOS device comprises a second N-well and a second P-substrate layer;
the first N-well overlaps with the second N-well; and
the first P-substrate layer overlaps with the second P-substrate layer.

7. The layout structure of claim 4, wherein
the first CMOS device comprises a first N-well and a first P-well;
the second CMOS device comprises a second N-well and a second P-well;
the first N-well overlaps with the second N-well; and
the first P-well overlaps with the second P-well.

8. The layout structure of claim 7, wherein
the first CMOS device further comprises a first N-type S/D region and a first P-type S/D region;
the second CMOS device further comprises a second N-type S/D region and a second P-type S/D region;
the first N-type S/D region overlaps with the second N-type S/D region; and
the first P-type S/D region overlaps with the second P-type S/D region.

9. The layout structure of claim 8, wherein
each of the first and second, N-type and P-type S/D regions has a diffusion region of the same conductivity type at its periphery;
the diffusion region of the first N-type S/D region overlaps with the diffusion region of the second N-type S/D region; and
the diffusion region of the first P-type S/D region overlaps with the diffusion region of the second P-type S/D region.

10. The layout structure of claim 8, wherein
each of the first and second, N-type and P-type S/D regions has at least one contact thereon;
the contact on the first N-type S/D region overlaps with the contact on the second N-type S/D region; and
the contact on the first P-type S/D region overlaps with the contact on the second P-type S/D region.
